(19) United States
(12) Patent Application Publication
(10) Pub. No.: US 2017/0047464 A1
(43) Pub. Date: Feb. 16, 2017

(54) THERMOPLASTIC WIRE NETWORK SUPPORT FOR PHOTOVOLTAIC CELLS

(71) Applicant: Beijing Apollo Ding Rong Solar Technology Co., Ltd., BEIJING (CN)

(72) Inventor: Todd Krajewski, Mountain View, CA (US)

(21) Appl. No.: 15/243,622

(22) Filed: Aug. 22, 2016

Related U.S. Application Data
(63) Continuation of application No. 13/085,274, filed on Apr. 12, 2011, now abandoned.
Application No. 13/085,274 is a continuation-in-part of application No. 12/566,555, filed on Sep. 24, 2009, now abandoned.
Application No. 12/566,555 is a continuation-in-part of application No. 12/052,476, filed on Mar. 20, 2008, now Pat. No. 8,912,429.

(51) Int. Cl. H01L 31/048; H01L 31/02; H01L 31/05

(52) U.S. Cl. CPC H01L 31/048; H01L 31/0504; H01L 31/0201

(57) ABSTRACT

Provided are novel methods of fabricating photovoltaic modules using thermoplastic materials to support wire networks to surfaces of photovoltaic cells. A thermoplastic material goes through a molten state during module fabrication to distribute the material near the wire-cell surface interface. In certain embodiments, a thermoplastic material is provided as a melt and coated over a cell surface, with a wire network positioned over this surface. In other embodiments, a thermoplastic material is provided as a part of an interconnect assembly together with a wire network and is melted during one of the later operations. In certain embodiments, a thermoplastic material is provided as a shell over individual wires of the wire network. A thermoplastic material is then solidified, at which point it may be relied on to support the interconnect assembly with respect to the cell. Also provided are novel photovoltaic module structures that include thermoplastic materials used for support.

### CROSS-REFERENCE TO RELATED APPLICATIONS

This application is a continuation of U.S. patent application Ser. No. 13/085,274 entitled “THERMOPLASTIC WIRE NETWORK SUPPORT FOR PHOTOVOLTAIC CELLS,” filed Apr. 12, 2011, (Attorney Docket MSOLP061), which is a continuation-in-part of U.S. patent application Ser. No. 12/566,555 (now abandoned), entitled “INTERCONNECT ASSEMBLY,” filed Sep. 24, 2009, (Attorney Docket MSOLP009), which is a continuation-in-part of U.S. patent application Ser. No. 12/052,476 (now U.S. Pat. No. 8,912,429), entitled “INTERCONNECT ASSEMBLY,” filed Mar. 20, 2008, (Attorney Docket MSOLP009), each of which is incorporated by this reference and for all purposes.

### BACKGROUND

In the drive for renewable sources of energy, photovoltaic technology has assumed a preeminent position as a cheap and renewable source of clean energy. For example, photovoltaic cells using a Copper Indium Gallium Diselenide (CIGS) absorber layer offer great promise for thin-film photovoltaic cells having high efficiency and low cost. Of comparable importance to the technology used to fabricate thin-film cells themselves is the technology used to collect electrical current from the cells and to interconnect one photovoltaic cell to another to form a photovoltaic module.

Just as the efficiency of thin-film photovoltaic cells is affected by parasitic series resistances, photovoltaic modules fabricated from multiple cells are also impacted by parasitic series resistances and other factors caused by electrical connections to the absorber layer and other electrical connections within the modules. A significant challenge is the development of current collection and interconnection structures that improve the overall performance of the module. Moreover, the reliability of photovoltaic modules is equally important as it determines their useful life, cost effectiveness, and viability as reliable alternative sources of energy.

### SUMMARY

Provided are novel methods of fabricating photovoltaic modules using thermoplastic materials to support wire networks on surfaces of photovoltaic cells. A thermoplastic material goes through a molten state during module fabrication to distribute the material near the wire-cell surface interface. In certain embodiments, a thermoplastic material is provided as a melt and coated over a cell surface, with a wire network positioned over this surface. In other embodiments, a thermoplastic material is provided as a part of an interconnect assembly together with a wire network and is melted during one of the later operations. In certain embodiments, a thermoplastic material is provided as a shell over individual wires of the wire network. A thermoplastic material is then solidified, at which point it may be relied upon to support the interconnect assembly with respect to the cell. Also provided are novel photovoltaic module structures that include thermoplastic materials used for support.

In certain embodiments, a method of fabricating a photovoltaic module involves providing a photovoltaic cell including a surface and providing an interconnect wire network assembly including a conductive wire network, and establishing an electrical contact between a portion of the conductive wire network and the surface of the photovoltaic cell. When the contact is established the conductive wire network is aligned in a predetermined manner with respect to the photovoltaic cell. The method also involves providing a molten thermoplastic polymer adjacent to an interface between the portion of the conductive wire network and the surface of the photovoltaic cell. The molten thermoplastic polymer may be provided before establishing the electrical contact, e.g., by melting a coating provided on individual wires of the wire network. Alternatively, the molten thermoplastic polymer may be provided after establishing the electrical contact, e.g., by coating an assembly including the cell and wire network with the molten thermoplastic polymer. The method also involves cooling the molten thermoplastic polymer to form a solid polymer configured to provide mechanical support to the conductive wire network with respect to the surface of the photovoltaic cell during one or more subsequent processing operations and operation of the photovoltaic module.

In certain embodiments, a melting temperature of the thermoplastic polymer exceeds a maximum predefined operating temperature of the photovoltaic module. For example, a melting temperature of the thermoplastic polymer may be at least about 120° C. Cooling may thermoplastic polymer involves maintaining the alignment between the conductive wire network and the photovoltaic cell.

In certain embodiments, a thermoplastic polymer is provided as a part of the interconnect wire network assembly. For example, the thermoplastic polymer may be provided as a shell enclosing individual wires of the conductive wire network. This thermoplastic polymer is opaque. The thickness of the shell may be between about 0.5 microns and 5 microns. In some of these embodiments, establishing an electrical contact between the portion of the conductive wire network and the surface of the photovoltaic cell involves melting the thermoplastic polymer. In other embodiments, providing the thermoplastic polymer involves coating a portion of the conductive wire network positioned on the surface of the photovoltaic cell with the molten thermoplastic polymer. A molten thermoplastic polymer may be provided after establishing the electrical contact between the portion of the conductive wire network and the surface of the photovoltaic cell.

Some examples of thermoplastic polymers include an ionomer, an acrylate, an acid modified polyolefin, an anhydride modified polyolefin, a polyimide, a polyamide, a liner low density polyethylene, and a cross-linkable thermoplastic. In certain embodiments, a thermoplastic polymer is provided without a liner. This method may be used for supporting an interconnect wire network on a front light incident surface of the photovoltaic cell. A wire network includes one or more wires having a gauge of between about 34 and 46.

In certain embodiments, providing a thermoplastic polymer in a molten state involves melting the thermoplastic polymer by passing an electrical current through the conductive wire network. In the same or other embodiments, providing a thermoplastic polymer in a molten state involves heating the surface of the photovoltaic cell. Establishing an electrical contact and/or providing a thermoplastic polymer may involve passing a pre-aligned stack of the photovoltaic cell and the interconnect wire network assembly through a set of heated nip rollers. The method may also include one or more subsequent processing operations for testing the electrical contact between the wire network and the surface of the photovoltaic cell and/or heating the solid polymer during lamination of the photovoltaic module such that the solid polymer does not melt during heating. The manner of alignment between the conductive wire network and the photovoltaic cell may be maintained during cooling the molten thermoplastic polymer. In certain embodiments, a conductive wire network and photovoltaic cell change their initial alignment in the predetermined manner prior to cooling the molten thermoplastic polymer.

Provided also a photovoltaic module including a first photovoltaic cell including a first surface, a conductive wire network having a first portion in direct contact and electrical communication with the first surface, and a thermoplastic material positioned adjacent to an interface between the first portion of the conductive wire network and the first surface. The thermoplastic material provides support to the first portion of the conductive wire network with respect to the first surface of the first photovoltaic cell. The melting temperature of the thermoplastic material may exceed an operating temperature of the photovoltaic module. The module also includes a layer of the encapsulant material in direct contact with the thermoplastic material. The encapsulant material fills topographical voids created by the portion of the conductive wire network and/or the thermoplastic material. In certain embodiments, the melting temperature of the thermoplastic materials is substantially higher than a melting temperature of the encapsulant material. In certain embodiments, the photovoltaic module also includes a second photovoltaic cell having a second surface in direct contact and electrical communication with a second portion of the conductive wire network and a liner including an adhesive surface providing support to the second portion of the conductive wire network with respect to the second surface. An operating temperature of the photovoltaic module may correspond to a maximum predetermined operating temperature.

These and other features are described further below with reference to the figures.

### BRIEF DESCRIPTION OF THE DRAWINGS

FIG. 1 is a schematic top view of a photovoltaic module having multiple photovoltaic cells electrically interconnected using interconnect wire network assemblies, in accordance with certain embodiments.

FIG. 2A is a schematic side view of two photovoltaic cells interconnected using a wire network assembly, in accordance with certain embodiments.

FIG. 2B is a schematic side view of a bus bar connected to a photovoltaic cell, in accordance with certain embodiments.

FIG. 2C is a schematic side view of another bus bar connected to another photovoltaic cell, in accordance with other embodiments.

FIG. 3 is a schematic cross-sectional view of a wire network attached to a surface of a photovoltaic cell under an encapsulant layer and a sealing sheeting, in accordance with certain embodiments.

FIG. 4 illustrates a process flowchart corresponding to a method of fabricating a photovoltaic module, in accordance with certain embodiments.

FIG. 5A is a schematic cross-sectional view of a wire coated with a thermoplastic material prior to making an electrical connection to a surface of the photovoltaic cell, in accordance with certain embodiments.

FIG. 5B is a schematic cross-sectional view of the same wire after making the electrical connection to the surface of the photovoltaic cell, in accordance with certain embodiments.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

Making electrical connections to the front and back surfaces of a photovoltaic cell, for example a Copper Indium Gallium Diselenide (CIGS) cell, can be challenging.

Not only do these electrical connections need to have a relatively low electrical resistance and meet various rigorous requirements that are specific to photovoltaic modules (e.g., minimize light shading of the front surface), but these connections also have to withstand harsh operating conditions over the entire operating lifetime of the photovoltaic module. For example, a typical photovoltaic module continuously goes through temperature cycling during its operation (for example, between high temperatures in the middle of a hot, sunny day and low temperatures later at night). The temperature difference in a single day may exceed 100° C. These temperature fluctuations may be even more during longer periods that further add seasonal variations and various weather extremes. The temperature fluctuations may be further amplified by certain designs of the photovoltaic module. For example, some rigid modules may be supported at a distance from the roof surface by metal brackets, which allow for ventilation and cooling to occur underneath the module. Various flexible and building integrable photovoltaic modules may have very small gaps or no gaps at all between the back sides of these modules and, for example, the supporting building structure. As a result, these later types of modules may get substantially hotter when exposed to the same weather conditions.

The electrical connections to the front and back surfaces of the photovoltaic cells in the module may be made using interconnect wire network assemblies. These assemblies typically include wire networks. A wire network may include one wire, such as a serpentine-shaped wire, or multiple wires, such as multiple substantially parallel wires. One portion of the wire network may be placed in direct contact with a front surface or a back surface of the cell during module fabrication. The other portion may be connected to another cell, such as its front surface or back surface, or connected to other electrical components of the module, such as bus bars. In specific embodiments used to form in-series connections between cells, one portion of the network is placed in contact with a front surface of one cell while another portion of the same network is placed in contact with a back surface of another cell. Other types of connections between cells using interconnect wire network assemblies are possible as well, such as parallel connections or various combinations of in-series and parallel connections. Furthermore, an interconnect assembly may be used for uniform current collection from relatively resistive surfaces of the photovoltaic cells, such as front surfaces containing transparent conductive oxides.

The wire network may be supported with respect to the cell surface by various polymer materials. For example, a polymer material may be formed into a structure positioned adjacent to the wire-cell surface interface. The polymer material may be bonded to the wire network and surface, for example, by melting the material and distributing it on the surfaces of these two components. In certain embodiments, a polymer structure may form an enclosure around a wire that keeps the wire in contact with the cell surface. In these embodiments, the polymer material does not need to stick to the wire surface.

The wire network support has to be maintained during the entire operating lifetime of a photovoltaic module and be able to withstand the expected temperature variations experienced by the module. The support also has to withstand some stresses generated at the wire-cell surface interface. Specifically, various module components may have different coefficients of thermal expansion (CTEs), and some stresses may be generated during temperature fluctuations. If a polymer material used for support becomes soft and less mechanically stable, for example, at some elevated temperature, then it may allow the wire to move with respect to the cell under one of these stresses. This phenomenon is sometimes referred to as “wire floating.” Wire floating can be detrimental to cell performance and cause losses of electrical connections (by separation of a wire from the cell surface) and degradation of the overall cell performance.

Some conventional wire support structures use multi-layered films that may be difficult to manufacture and process. Furthermore, many such films are applied over the entire front side surface of the cells and, therefore, need to be made from transparent materials. This transparency requirement substantially limits material options and module designs. Generally, a multi-layered film has at least one layer that is mechanically stable even at high temperatures. For purposes of this document, this stability may be referred to as a “thermal stability,” which is defined as the ability of a polymer material to withstand mechanical forces at certain elevated temperatures that are generally within a range of normal operating temperatures of the photovoltaic module and may correspond to the maximum operating temperature of the photovoltaic module. As noted above, the normal and maximum operating temperatures may depend on the module design, its operating climate zone, and various other factors. In certain embodiments, the maximum operating temperature is at least about 90° C. or, more specifically, at least about 95° C. It should be noted that for certification testing, the materials may need to perform at about 20° C. above the maximum operating temperature.

Therefore, in certain embodiments, materials remain mechanically stable at temperature of at least about 110° C., or more specifically, at temperatures of at least about 115° C. A thermally stable layer of the multi-layered film provides some support to other layers and wire networks when the temperature inside the module rises (for example, during its daytime operation). The other layers may melt at some temperature levels, which may cause some wire floating. These other layers are typically used to provide adhesion to wires and cell surfaces at low temperatures, such as room temperature, during fabrication of the module. These layers may have some tackiness at room temperature and can provide adhesion of the multi-layered structure to wires and cell surfaces.

It has been found that wire floating may be substantially reduced and module performance substantially improved by using polymer materials that are mechanically stable at high temperatures (or “thermally stable” as defined above). These thermally stable polymer materials may be used by themselves without any additional less-stable materials. Specifically, some polymer formulations may be used that have high melting and/or glass transition temperatures and provide good wetability to typical wire surfaces and cell surfaces in the molten state. In certain embodiments, some polymer materials have glass transition temperatures exceeding the maximum operating temperature of the module. In the same or other embodiments, the melting point of suitable materials is at least about 100° C. or, more specifically, of at least about 110° C. or even at least about 120° C.

During module fabrication, a thermoplastic material may be melted or provided in a molten state in order to distribute this material at desirable locations, such as adjacent to the wire-cell surface interface. The molten material may be distributed in a substantially void free manner. While the wire network remains aligned with respect to the cell, the thermoplastic material is cooled down to form a solid material that is capable of providing mechanical support to the wire network. Due to its high thermal stability, the thermoplastic material maintains this support while the module goes through further fabrication operations that may involve heating, such as lamination, as well as during operation of the module when the module undergoes various temperature fluctuations as described above.

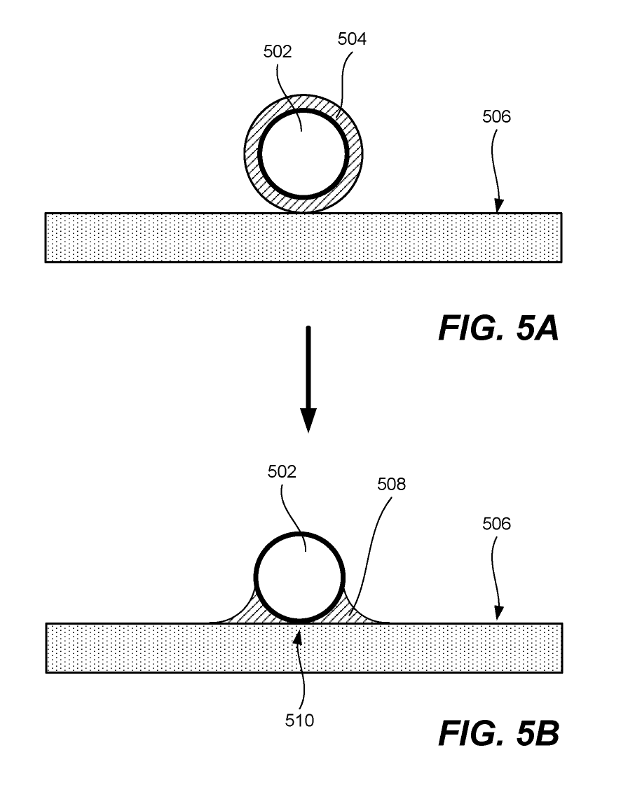

In certain embodiments, a thermoplastic material may be specifically patterned to cover only small portions of the cell surface adjacent to the wires. For example, a thermoplastic material may be provided as a shell positioned around individual wires of the wire network. When the thermoplastic shells are melted during fabrication, the molten material pools stay adjacent to the wire-cell interfaces rather than spreading across the entire surface of the cell. The molten pools are then solidified to form compact structures adjacent to the wire cell interfaces as, for example, shown and further described with reference to FIG. 5. Even small contact areas between the cell surface and thermoplastic material may provide a sufficiently strong bond to this surface. This approach allows using various opaque thermoplastic materials for supporting wires over front light incident surfaces of the photovoltaic cells. The cell performance is generally not sacrificed because additional shading of the cell surface by the thermoplastic material structures is minimal. Opacity provides more material options than in the conventional supporting structures described above and allows new designs and features.

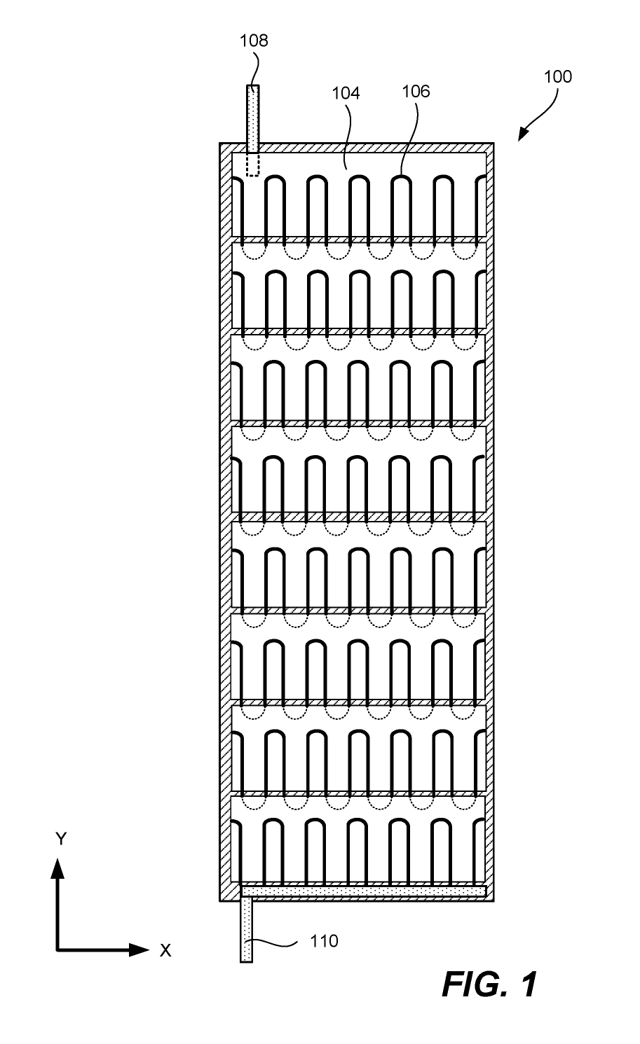

To provide a better understanding and context for methods of fabricating photovoltaic modules, some examples of photovoltaic modules will now be described in more detail. FIG. 1 is a schematic top view of photovoltaic module 100, in accordance with certain embodiments. Module 100 includes multiple photovoltaic cells 104 electrically interconnected using interconnect wire network assemblies 106.

Specifically, all cells 104 shown in FIG. 1 are electrically interconnected in series such that each cell pair has one interconnect assembly extending over a front surface of one cell and extending under a back surface of another cell. Module 100 shown in FIG. 1 includes eight photovoltaic cells 104 that are interconnected using seven assemblies 106. However, it will be understood by one of ordinary skill in the art that any number of cells may be positioned within one module.

Multiple cells or sets of cells may be interconnected in series to increase a voltage output of the module, which may be driven by electricity transmission and other requirements. For example, a typical voltage output of an individual CIGS cell is between 0.4V and 0.7V. Modules built from CIGS cells are often designed to provide voltage outputs of at least about 20V and higher. In addition to interconnecting multiple cells in series, a module may include one or more module-integrated inverters to regulate its voltage output. Interconnect assemblies may be also used to connect multiple cells in parallel or various combinations of the two connection schemes (i.e., parallel and in-series connection schemes).

Each interconnect assembly 106 illustrated in FIG. 1 includes a serpentine-shaped wire extending across the length of photovoltaic cells 104 (X direction). Bottom portions (with respect to the module orientation presented in FIG. 1) of the serpentine-shaped wire extend under a corresponding lower cell (with respect to the wire) to make an electrical connection to the back side of this cell. These portions are illustrated with dashed lines overlapping with the photovoltaic cells' boundaries. In certain embodiments, these “under the cells” portions may also include conductive tabs welded to the wires in order to increase the surface contact area with the back sides of the cells. A top portion of each wire is shown to extend over a front side of a corresponding upper cell (with respect to the wire) and make an electrical connection to the front side. Other types of wire networks (e.g., multiple parallel wires) and/or interconnect assemblies may be used as well.

Most interconnect assemblies 106 are used to connect a pair of cells and, therefore, extend over both a front side of one cell and under a back side of the other cell. From a photovoltaic cell perspective, most cells 104 have one interconnect assembly 106 extending over its front side and another assembly 106 extending under its back side. However, some end-cells (e.g., the top-most cell in FIG. 1) may have only one interconnect wire network assembly 106 extending over one of its sides, typically over its front side. In these embodiments, bus bars or other electrical components of the module may be electrically coupled directly to the other side of such a cell, typically its back side.

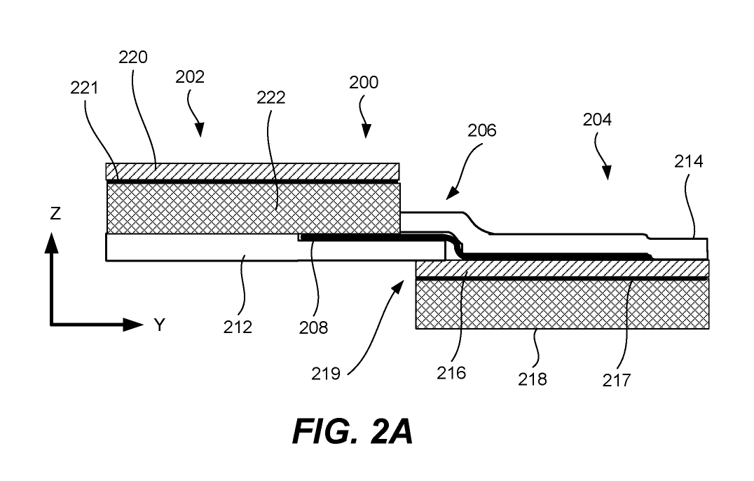

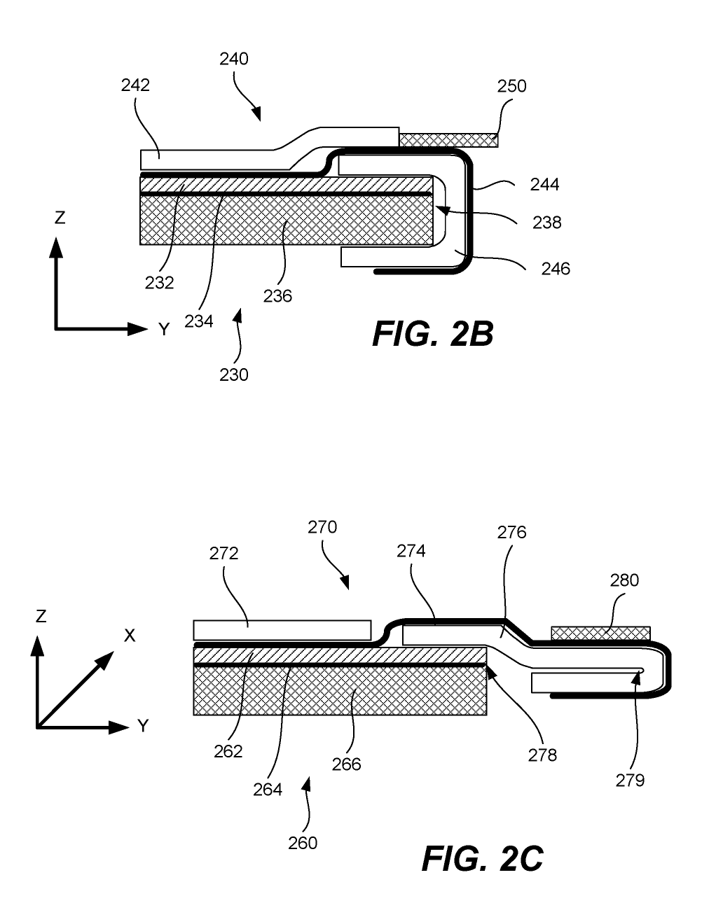

For example, FIG. 1 illustrates a portion of top bus bar 108 extending under and connecting directly to the back side of the top cell without any intermediate interconnect assemblies. Still, some end-cells (e.g., the bottom cell in FIG. 1) may be in contact with two interconnect wire network assemblies 106. A bus bar may be coupled to one or more interconnect assemblies, such as bottom bus bar 110 shown electrically coupled to the bottom portion of assembly 106. In certain embodiments, a bus bar may be coupled to an assembly prior to attaching this assembly to a cell. As such, a number of coupling techniques that are generally not suitable for coupling to the cell, such as welding and soldering, may be used for attaching the bus bar to the interconnect assembly. Some examples of connections between bus bars and interconnect assemblies are described in more detail with reference to FIGS. 2B and 2C.

In certain embodiments, a front surface of the cell includes one or more transparent conductive oxides (TCO), such as zinc oxide, aluminum-doped zinc oxide (AZO), indium tin oxide (ITO), and gallium doped zinc oxide. The layer forming this surface is typically referred to as a top conductive layer or a top layer. A typical thickness of the top conductive layer is between about 100 nanometers to 1,000 nanometers or, more specifically, between about 200 nanometers and 800 nanometers, with other thicknesses within the scope. The top conductive layer provides an electrical connection between the photovoltaic layer (positioned underneath the top conductive layer) and portions of the interconnect assembly. Due to the limited conductivity of the top conductive layer, wires of the assembly typically extend over substantially all front surface of the cell.

In the same or other embodiments, a back surface of the cell includes a conductive substrate supporting the photovoltaic layer as well as collecting electrical current from this layer. Some examples of a photovoltaic layer or stack include CIGS cells, cadmium-telluride (Cd—Te) cells, amorphous silicon (a-Si) cells, microcrystalline silicon cells, crystalline silicon (c-Si) cells, gallium arsenide multi-junction cells, light adsorbing dye cells, and organic polymer cells. However, other types of photovoltaic stacks may be used as well. While interconnect assemblies generally do not make direct connections to the stack, various characteristics of the photovoltaic stack create specific requirements for the design of the interconnect assemblies. Some examples of conductive substrates include stainless steel foil, titanium foil, copper foil, aluminum foil, beryllium foil, a conductive oxide deposited over a polymer film (e.g., polyamide), a metal layer deposited over a polymer film, and other conductive structures and materials. In certain embodiments, a conductive substrate has a thickness of between about 2 mils and 50 mils (e.g., about 10 mils), with other thicknesses also within the scope. Generally, a substrate is sufficiently conductive such that a uniform distribution of an assembly's components (e.g., wires) adjacent to the substrate is not needed.

As described above, portions of interconnect wire network assemblies are electrically coupled to the front and/or back surfaces of the photovoltaic cells. This coupling is typically provided by direct physical contact between wires of the wire networks and cell surfaces. The physical contact may be maintained by bonding the cell and wires together using some other components, such as thermally stable thermoplastic materials provided adjacent to the wire-cell interface.

FIG. 2A illustrates a schematic side view of a module portion 200 that includes two photovoltaic cells 202 and 204 electrically interconnected using an assembly 206, in accordance with certain embodiments. Assembly 206 includes one or more wires forming a wire network 208, a bottom carrier structure 212, and a top carrier structure 214. Top carrier structure 214 attaches a portion of wire network 208 to a top layer 216 of cell 204 to provide an electrical connection between these two components or, more specifically, between the wires of wire network 208 and the front side surface of top layer 216. This electrical connection may require a certain overlap (in the Y direction) between wire network 208 and top layer 216, which generally depends on the electrical properties of top layer 216. Top layer 216 is positioned over a photovoltaic layer 217 and used to interconnect photovoltaic layer 217 and wire network 208. Top layer 216 and photovoltaic layer 217 are supported by substrate layer 218, which acts as another current collector from photovoltaic layer 217. Substrate layer 218 may be connected to other electrical components of the module (not shown).

Bottom carrier structure 212 attaches another portion of wire network 208 to bottom substrate layer 222 of cell 202 in order to make an electrical connection between these two components or, more specifically, between the wires of network 208 and the bottom surface of substrate layer 222. Substrate layer 222 may have a higher conductivity than a corresponding top layer. As such, wire network 208 may not need to overlap as much with substrate layer 222 as with the top layer. Substrate layer 222 provides support to a photovoltaic layer 221 and top layer 220. Top layer 220 may be connected to other electrical components of the module (not shown).

In addition to attaching wire networks to the front and back side surfaces of the cells, carrier structures may be used to electrically insulate various components in the module. For example, FIG. 2 illustrates bottom carrier structure 212 slightly extending over top layer 216 of adjacent cell 204. This overlap separates the wires of wire network 208 from edge 219 of cell 204 and prevents these wires from shorting top layer 216 and substrate layer 218. Top layer 216 and photovoltaic layer 217 are relatively thin and may be easily damaged by wire network 208, which is prevented by bottom carrier structure 212 slightly extending over top layer 216.

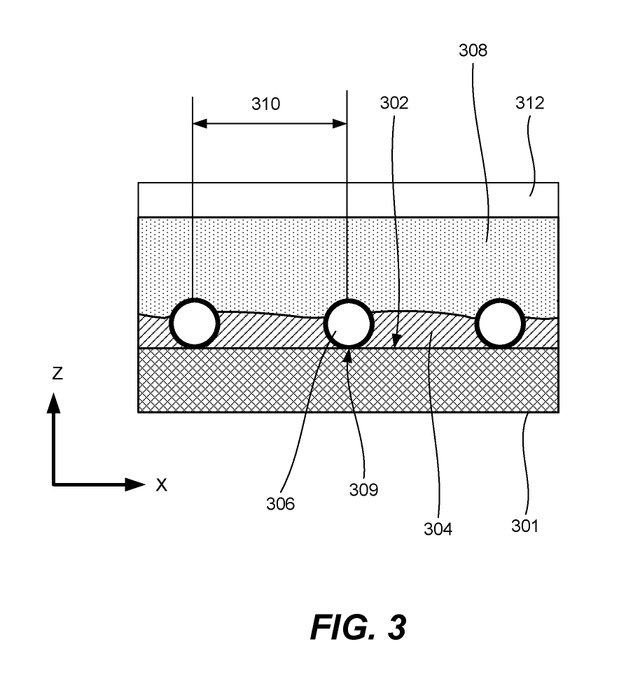

Carrier structures used for attaching interconnect assemblies to photovoltaic cells may have various designs and configurations. In certain embodiments, a bottom carrier structure is different than a corresponding top carrier structure. As explained above, these two types of structures attach wire networks to different surfaces, and different bonding materials may be used for these different purposes. Furthermore, top carrier structures should not block light and, therefore, should either be made of substantially transparent materials or cover only small portions of the front cell surface. Finally, the two types of structures are generally attached to cells at different stages of the overall module fabrication process. In certain embodiments, a front carrier structure and its corresponding wire network are attached to a stand alone cell that may not have any other components attached to it. This combination of a wire network and a cell will be referred to as a subassembly. The subassembly may be then tested for an electrical connection between the wire network and the front side surface. Then, it may be aligned with other subassemblies (that each include a cell and a wire network), such that a portion of the wire network of the original assembly extends under a back side surface of the cell in an adjacent assembly. Attaching the bottom carrier structure of the original subassembly to this back side of the cell of the adjacent subassembly may be performed at later stages, (for example, immediately prior, during, or even after lamination of the entire module). A bottom carrier structure, in these embodiments, may include a thermally stable liner and one or more adhesive layers disposed on one or both sides of the liner that allow forming initial subassemblies. Some examples of bottom carrier structure materials include polyethylene terephthalate (PET), polyethylene naphthalate (PEN), poly(ethylene-co-tetrafluoroethylene (ETFE), ionomer resins (e.g., poly(ethylene-co-methacrylic acid)), polyamide, polyetherimide (PEI), polyetheretherketone (PEEK), or combinations of these. One particular example is SURLYN®, available from E. I. du Pont de Nemours and Company in Wilmington, Del. For example, a support structure may have three polymer layers, such as a co-extruded stack containing SURLYN®, PET, and another layer of SURLYN® (with the PET layer positioned in between the two SURLYN® layers). In the same embodiments, a top carrier structure may include a thermally stable thermoplastic material, which may be a part of the subassembly or provided later. In either case, the top carrier structure, unlike the bottom carrier structure, may not include a liner. Some examples of the top carrier structure are further described below with reference to FIG. 3.

In other embodiments, both types of carrier structures have substantially the same design and include a thermoplastic material disposed adjacent to the wire-cell surface interface in the fully assembled module. Neither one of these carrier structures include a separate liner. However, a thermoplastic material may form a continuous layer covering a substantial portion of the cell surface. In other embodiments, a thermoplastic material may form individual structures positioned adjacent to the wire-cell surface interface, and the portions of the surface in between individual wires are not covered by the thermoplastic material.

As noted above with reference to FIG. 1, interconnect wire network assemblies may be used to provide electrical connections between cells and bus bars. Furthermore, carrier structures of these assemblies may be used to protect edges of the photovoltaic cells, which will now be further explained with reference to FIGS. 2B and 3C. FIG. 2B is a schematic side view of a bus bar 250 connected to a photovoltaic cell 230 using an interconnect wire network assembly 240, in accordance with certain embodiments. This design may be used when spacing inside the module in Y direction is limited, and packing of the cells and other components in this direction should be optimized.

Photovoltaic cell 230 includes a photovoltaic layer 234 and two conductive layers positioned on both sides of it (i.e., a top layer 232 and a substrate layer 236). As described above, top layer 232 and substrate layer 236 provide current collection from photovoltaic layer 234. Furthermore, substrate layer 236 may provide mechanical support for the entire stack. Interconnect assembly 240 includes top carrier structure 242, wire network 244, and bottom carrier structure 246. Interconnect assembly 240 may be the same as various assemblies used for connecting two cells as described above with reference to FIG. 2A. Some features of these assemblies are also described below with reference to other figures. Wire network 244 is electrically coupled to top layer 232 of cell 230 by a direct physical contact between layer 232 and the wires of wire network 244. Top carrier structure 242 supports wire network 244 with respect to top layer 232. Bus bar 250 is attached to wire network 244 by direct physical contact, welding, soldering, or any other attachment techniques. Bus bar 250 may be attached to wire network 244 prior to attaching the entire interconnect assembly 240 to photovoltaic cell 230. As shown in FIG. 2B, bus bar 250 may be positioned above cell 230 and attached to wire network 244 above top layer 232 of cell 230 (in the Z direction). Alternatively (not shown), bus bar 250 may be positioned below cell 230 and attached to wire network below substrate layer 236.

Bottom carrier structure 246 extends over edge 238 (in a direction opposite of Y direction) and prevents the wires of wire network 244 from shorting top layer 232 and substrate layer 236. Bottom carrier structure 246 may be folded around edge 238 and make a contact to substrate layer 236. In certain embodiments, bottom carrier structure 246 is adhered to substrate layer 236. For example, bottom carrier structure 246 may have two adhesive surfaces. One of these surfaces may be used for adhering bottom carrier structure 246 to top layer 232 and/or substrate layer 236. Another surface may be used for adhering bottom carrier structure 246 to top carrier structure 242 (if there is an overlap as shown in FIG. 2B), bus bar 250, and/or a wire of wire network 244. In other embodiments, bottom carrier structure 246 has only one adhesive surface and is adhered only to a subset of the above mentioned components. In yet another embodiment, bottom carrier structure 246 has no adhesive surfaces, and it may be supported by other components.

Similar to bottom carrier structure 246, wire network 244 may be bent around edge 238 to avoid unnecessarily occupying space in Y direction. Wire network 244 should not come in contact with substrate layer 236 in order to avoid shorting cell 230. Therefore, bottom carrier structure 246 should be slightly longer than the wires of wire network 244 (under the substrate layer 236 and in the direction opposite to Y direction). The fold around edge 238 created by wire network 244 may also help support the bottom support structure with respect to this edge.

FIG. 2C is a schematic side view of a bus bar 280 connected to a photovoltaic cell 260 using an interconnect assembly 270, in accordance with other embodiments. This configuration may be used when spacing in Z direction is limited, and a flat profile of cells and other components is desirable. Similar to embodiments presented above with reference to FIG. 2B, photovoltaic cell 260 includes a substrate layer 266 supporting a photovoltaic layer 264 and a top layer 262. Interconnect assembly 270 includes top support structure 272, wire network 274, and bottom support structure 276. Interconnect assembly 270 may also be the same as an assembly used for connecting two cells as described above with reference to FIG. 2A. Top support structure 272 provides support to wire network 274 with respect to cell 260 and ensures mechanical and electrical connection between top layer 262 and wire network 274. Wire network 274 is attached to bus bar 280 and provides electrical connection between top layer 262 and bus bar 280. Bus bar 280 may be attached to wire network 274 by direct contact, welding, soldering, or any other attachment technique. Bus bar 280 may be attached to wire network 274 prior to attaching the entire interconnect assembly 270 to photovoltaic cell 260.

Bottom support structure 276 extends over edge 278 (in a direction opposite of Y direction) and prevents the wires of wire network 274 from shorting top layer 262 and substrate layer 266. Bottom support structure 276 extends away from edge 278 in Y direction and is folded over axis 279 (extending in Z direction). Bottom support structure 276 may have at least one adhesive surface for attaching to top layer 262 and to itself in the folded portion. In other embodiments, bottom support structure 276 has two adhesive surfaces. For example, the second adhesive surface may be used for adhering bus bar 280 to wire network 274. In yet another embodiment, bottom carrier structure 246 has no adhesive surfaces, and it may be supported by physical contact with other components. For example, the folded portion may be supported by the corresponding folded portion of wire network 274. The folded end of wire network 274 should be separated from edge 278 by a distance or by some insulating components.

FIG. 3 is a schematic cross-sectional view of a wire network 306 attached to a surface 302 of photovoltaic cell 301, in accordance with certain embodiments. This attachment creates an interface 309 between wire network 306 and surface 302, which is commonly referred to as wire-cell surface interface 309. Depending on the profile of wires of the wire network and cell surface, interface 309 may correspond to multiple lines. Wire network 306 is supported on surface 302 using a thermoplastic material 304, which is positioned at least adjacent to wire-cell surface interface 309. Thermoplastic material 304 may cover a substantial part of surface 302 (i.e., in between the wires of wire network 306), as shown in FIG. 3. In other embodiments, a thermoplastic material forms individual patches that cover only some small portions of surface 302. In specific embodiments, less than about 5% of the surface is covered by the thermoplastic material or, more specifically, less than about 2%. Some of these later embodiments are described below with reference to FIGS. 5A and 5B. This feature allows using opaque thermoplastic materials over front surfaces of the cells without substantially sacrificing the performance of the cells.

Thermoplastic material 304 and portions of wire network 306 may form a topographically uneven surface (facing the direction opposite of Z direction). An encapsulant material 308 may be provided over this surface to fill any voids in between thermoplastic material 304 (and portions of wire network 306 if these portions protrude above thermoplastic material 304, as shown in FIG. 3) and sealing sheet 312. Various examples of encapsulant materials and sealing sheets are described in U.S. patent application Ser. No. 12/894,736 (Attorney Docket No. MSOLP037/IDF153) to Krajewski et al., entitled “THIN FILM PHOTOVOLTAIC MODULES WITH STRUCTURAL BONDS,” filed on Sep. 30, 2010, which is incorporated herein by reference in its entirety for purposes of describing various examples of encapsulant materials and sealing sheets.

Surface 302 may represent the front side surface of the cell (i.e., the light-incident surface) or the back side surface (i.e., the bottom substrate surface). Depending on the type of the surface, wire network 306 will contact different type of materials, such as a transparent conductive oxide or a metal substrate. In certain embodiments, the materials of the carrier structure may be specifically tailored to the requirement of the surface to which this carrier structure is attached. This includes thermally stable thermoplastic materials, liners (if liners are used), and various other materials.

Thermoplastic materials may have specific properties that allow melting these materials and distributing them in a void free manner during fabrication. Furthermore, these materials should provide support to wire networks with respect to cells during operation of the module, including various exposed temperature fluctuations. Some examples include ionomers, acrylates, acid modified polyolefins, anhydride modified polyolefins, polyimides, polyamides, and various cross-linkable thermoplastics. More specific examples include BYNEL® resins supplied by DuPont in Wilmington, Del. For example, the following may be used: Series 1100 acid-modified ethylene vinyl acetate (EVA) resins, Series 2000 acid-modified ethylene acrylate polymers, Series 2100 anhydride-modified ethylene acrylate copolymers, Series 3000 anhydride-modified EVA copolymers, Series 3100 acid- and acrylate-modified EVA resins, which provide a higher degree of bond strength that Series 1100 resins, Series 3800 anhydride-modified EVA copolymers with a higher level of vinyl acetate in the EVA component than the 3000 and 3900 series, Series 3900 anhydride-modified EVA resins with improved level of bonding to polyamides and EVOH, Series 4000 anhydride-modified high density polyethylene resins (HDPE) resins, Series 4100 anhydride-modified linear low density polyethylene (LLDPE) resins, Series 4200 anhydride-modified low density polyethylene (LDPE) resins, and Series 5000 anhydride-modified polypropylene (PP) resins. Another specific example includes JET-MELT® Polyolefin Bonding Adhesive 3731 supplied by 3M Engineered Adhesives Division in St. Paul, Minn. Some of these resins can be mixed with other resins or fillers, such as polypropylene and polystyrene resins, as well as various ionomers, in order to adjust their thermal stability, viscosity of the molten state during fabrication, and adhesion properties.

When thermoplastic material 304 is formed as a layer in the fully fabricated module, its thickness may be comparable to a cross-sectional dimension of the wires in wire network 306 (e.g., a diameter of the round wires or a thickness of the flat wires). In certain embodiments, the thickness is between about 25% and 100% of the cross-sectional dimension of the wires or, more specifically, about 50%. Various examples of wires that may be used for wire network 306 and their respective dimensions are described below. When thermoplastic material 304 is provided or deposited as patches (e.g., provided as a coating on the wires), then substantially less material may be used for bonding the wires to the cell surfaces. Some examples of these arrangements are further described below with reference to FIGS. 5A and 5B.

Wire network 306 may include one or more wires that are uniformly distributed within a predetermined wire boundary. For example, each network may include one serpentine-shaped wire (as shown in FIG. 1) or multiple parallel wires spaced apart along X direction. Arrangements of the wires in the network may be characterized by a pitch 310, which, for purposes of this document, is defined as a distance between the centers of two adjacent wires or two adjacent portions of the same wire. The pitch 310 determines the distance the electrical current travels through the surface layers of the cells prior to reaching the conductive wires. Reducing the pitch increases the current collection characteristics of the interconnect assembly. However, a smaller pitch also decreases the useful front surface area of the cell by covering the photovoltaic layer with non-transparent wires and causes more dense topography, which may be prone to voids and other imperfections. In certain embodiments, pitch 310 is between about 2 millimeters and 5 millimeters (e.g., about 3.25 millimeters), though other distances may be used, as appropriate.

Wires of wire network 306 are typically made from thin, highly conductive metal stock and may have round, flat, and other shapes. Examples of wire materials include copper, aluminum, nickel, chrome, tin, zinc, silver, or various alloys thereof. In some embodiments, a nickel coated copper wire is used. In certain embodiments, the wire is 24 to 56 gauge, or in particular embodiments, 32 to 56 gauge (for example, 40 to 50 gauge). In specific embodiments, the wire has a gauge of 34, 36, 40, 42, 44, or 46. Wires may have round, oval, square, rectangular, triangular, or multi-faceted profile. For example, a cross-sectional profile may have a star shape (e.g., a five-point star shape or a six-point star shape). The star-shaped wires may be used when the wires' high surface areas are needed for establishing mechanical and/or electrical connections to the cell surface. Additional wire examples are described in U.S. patent application Ser. No. 12/843,648, entitled “TEMPERATURE RESISTANT CURRENT COLLECTORS FOR THIN FILM PHOTOVOLTAIC CELLS,” filed Jul. 26, 2010, (Attorney Docket MSOLP039/IDF156), which is incorporated herein by reference in its entirety for purposes of describing additional wire examples.

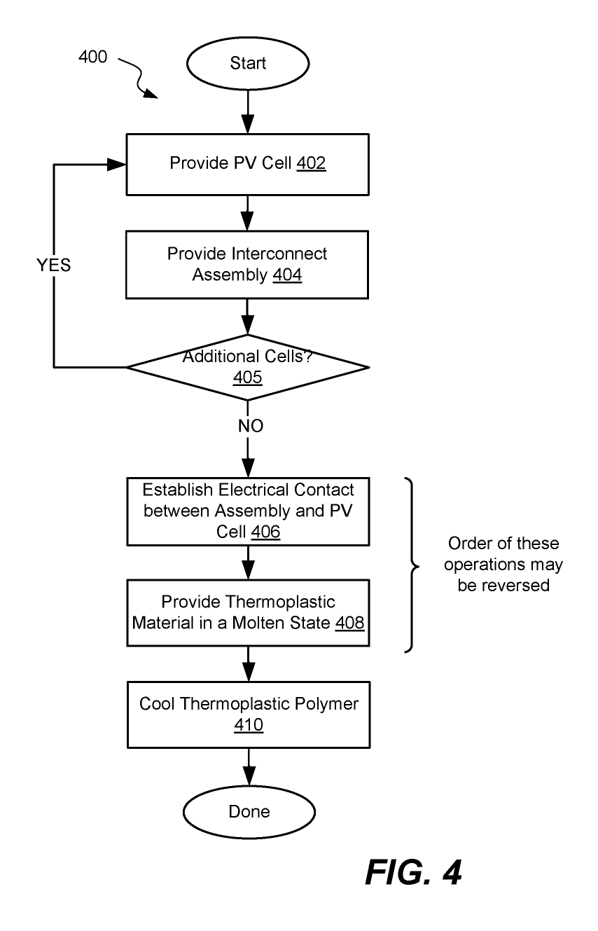

FIG. 4 illustrates a flowchart corresponding to a process 400 for fabricating a photovoltaic module, in accordance with certain embodiments. Process 400 may start with providing one or more photovoltaic cells in operation 402 and providing one or more interconnect wire network assemblies in operation 404. Various examples of photovoltaic cells and assemblies are described above. The provided interconnect assembly includes at least a wire network. It may also include a thermoplastic material. Alternatively, a thermoplastic material may be supplied in later operations (for example, during operation 408). In certain embodiments, a photovoltaic cell is provided with an interconnected assembly attached to one of its sides. The following operations in this process are used to attach a portion of this assembly to another cell.

Operations 402 and 404 may be repeated (decision block 405) to provide additional photovoltaic cells and/or interconnect assemblies. For example, all photovoltaic cells and interconnect assemblies of the module may be aligned during these initial operations prior to establishing final attachments between the cells and assemblies. In certain embodiments, a photovoltaic cell provided in operation 402 may be already bonded to an interconnect assembly provided in operation 404. In later operations, this interconnect assembly is bonded to another cell, and this cell may be bonded to another interconnect assembly.

Process 400 may proceed in operation 406 with establishing an electrical contact between a wire network of the interconnect assembly and a surface of the corresponding photovoltaic cell. For example, a wire network may include bare wires (i.e., insulated wires), which are placed in contact with the cell surface in operation 406, and a molten thermoplastic material may then be coated over this cell-wire network subassembly in operation 408.

In other embodiments, an interconnect assembly provided in operation 404 includes a thermoplastic material, which may or may not allow for wires of the assembly to make an immediate electrical contact with the cell surface. For example, a portion of the wire network may be exposed for making an electrical contact with the cell surface. In this case, process 400 may first proceed with operation 406 followed by melting and rearranging of the thermoplastic material in operation 408. Alternatively, wires of the wire network may be provided in operation 404 with the thermoplastic material forming a shell around the wire. The shell has to be at least partially melted before an electrical contact between the wires and cell surface can be established. One such example is shown in FIG. 5A, which illustrates a cross-sectional view of a wire 502 within a shell 504 formed by a thermoplastic material. FIG. 5A illustrates wire 502 prior to making an electrical connection to cell surface 506. Shell 504 may be only a few micrometers thick (for example, between about 1 micrometer and 5 micrometers for the typical wire sizes described above). Shell 504 is then melted to establish electrical contact between wire 502 and surface 506. As shown in FIG. 5B, the molten material 508 flows toward the wire-cell surface interface 510 due to various factors, such as gravity, surface tension, and the like. Wire 502 is also pushed towards surface 506 to establish the contact. Returning to FIG. 4, in this example, providing a thermoplastic material in a molten state in operation 408 is therefore performed prior to establishing an electrical contact between an assembly and cell in operation 406.

Process 400 then proceeds with cooling the molten thermoplastic material in operation 410. This cooling eventually solidifies the thermoplastic material and forms a permanent bond between the wire network and cell. Examples of cooling techniques involve exposing the final assembly to ambient conditions for a sufficient period of time, blowing cooling gases at the opposite surface of the cell, or any other technique. It should be noted that the alignment between the wire network and cell should be preserved at least during the initial cooling stage. Other operations may involve testing electrical contacts between the wire network and the surface of the photovoltaic cell and/or heating the assembly during lamination of the photovoltaic module. During this heating, the solid thermoplastic material formed in operation 410 remains substantially solid.

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

1-22. (canceled)

23. An apparatus comprising:
a first photovoltaic cell comprising a top cell surface and a bottom cell surface opposite the top cell surface;
a conductive wire network with a first wire network section and a second wire network section;
a first carrier structure that is a non-conductive material and has a first carrier structure top surface and a first carrier structure bottom surface opposite the first carrier structure top surface and separated by a nominal thickness; and
a bus bar, wherein:
a first portion of the first carrier structure bottom surface is in direct contact with the top cell surface,
the first wire network section is in direct contact and electrical communication with the top cell surface,
the second wire network section is in direct contact with a first portion of the first carrier structure top surface such that the second wire network section is not in direct contact with the top cell surface, and the second wire network section is in direct contact with and electrical communication with the bus bar.

24. The apparatus of claim 23, wherein:
the first portion of the first carrier structure top surface and the first portion of the first carrier structure bottom surface overlap when viewed at an angle perpendicular to the top cell surface, and
the second wire network section is offset from top cell surface in a direction perpendicular to the top surface by at least the nominal thickness of the carrier structure.

25. The apparatus of claim 24,
wherein a second portion of the first carrier structure bottom surface is in direct contact with the bottom cell surface.

26. The apparatus of claim 25, wherein:
the first portion of the first carrier structure bottom surface includes an adhesive that is in direct contact with the top cell surface, and
the second portion of the first carrier structure bottom surface includes an adhesive that is in direct contact with the bottom cell surface.

27. The apparatus of claim 26, wherein the first portion of the first carrier structure top surface includes an adhesive that is in direct contact with the second wire network section.

28. The apparatus of claim 25, wherein:
the conductive wire network further includes a third wire network section that is in direct contact with a second portion of the first carrier structure top surface,
the third wire network section overlaps with the second portion of the first carrier structure bottom surface when viewed at an angle perpendicular to the bottom cell surface and is offset from bottom cell surface in a direction perpendicular to the bottom cell surface by at least the nominal thickness of the carrier structure, and
the conductive wire network is not in direct contact with the bottom cell surface.

29. The apparatus of claim 28, wherein:
the first photovoltaic cell further includes a side cell surface that intersects with and spans between an edge of the top cell surface and an edge of the bottom cell surface,
a third portion of the first carrier structure bottom surface that is between the first portion of the first carrier structure bottom surface and the second portion of first carrier structure bottom surface and that extends over the side cell surface, and
the conductive wire network is not in direct contact with the side cell surface.

30. The apparatus of claim 24, further comprising a second carrier structure that is comprised of a thermoplastic material with a melting temperature that exceeds an operating temperature of the apparatus, wherein:
the second carrier structure is positioned adjacent to an interface between the first wire network section and the top cell surface, and
the second carrier structure attaches the first wire network section to the top cell surface.

31. The apparatus of claim 30, wherein:
the second carrier structure is further positioned adjacent to an interface between at least a part of the second wire network section and a part of the first portion of the first carrier structure top surface, and
the second carrier structure attaches the part of the second wire network section to the part of the first portion of the first carrier structure top surface.

32. The apparatus of claim 30, further comprising a layer of an encapsulant material, wherein the encapsulant material is in direct contact with the second carrier structure and fills topographical voids created by the first wire network section and/or by the second carrier structure.

33. The apparatus of claim 32, wherein the melting temperature of the second carrier structure is higher than a melting temperature of the encapsulant material.

34. The apparatus of claim 23, wherein the first carrier structure extends away from the first photovoltaic cell such that when viewed at an angle perpendicular to the top cell surface, the first portion of the first carrier structure, the second wire network section, and the bus bar do not overlap with the first photovoltaic cell.

35. The apparatus of claim 34, wherein:
the conductive wire network further includes a fourth wire network section in between the first wire network section and the second wire section that is in direct contact with a third portion of the first carrier structure top surface, and
the third portion of the first carrier structure top surface and the fourth wire network section overlap with the first portion of the first carrier structure bottom surface when viewed at an angle perpendicular to the top cell surface.

36. The apparatus of claim 34, wherein the first carrier structure bottom surface further comprises an adhesive that contacts the top cell surface.

37. The apparatus of claim 34, wherein the first carrier structure is positioned such that a fourth portion of the first carrier structure bottom surface is in direct contact with a fifth portion of the first carrier structure bottom surface.

38. The apparatus of claim 37, wherein the fourth portion of the first carrier structure bottom surface is adhered to the fifth portion of the first carrier structure bottom surface.

39. The apparatus of claim 37, wherein a fifth wire network section is in direct contact with a fourth portion of the first carrier structure top surface that is opposite to and overlaps with the fourth portion of the first carrier structure bottom surface when viewed at an angle perpendicular to the fourth portion of the first carrier structure bottom surface.

40. The apparatus of claim 39, wherein the fifth wire network section is offset from the photovoltaic cell by a first distance.

41. The apparatus of claim 39, wherein the fifth wire network section is adhered to the fourth portion of the first carrier structure top surface.

42. The apparatus of claim 34, further comprising a second carrier structure that is comprised of a thermoplastic material with a melting temperature that exceeds an operating temperature of the apparatus, wherein:
the second carrier structure is positioned adjacent to an interface between the first wire network section and the top cell surface, and
the second carrier structure attaches the first wire network section to the top cell surface.
